(19) United States
(12) Patent Application Publication
(10) Pub. No.: US 2009/0065354 A1
(43) Pub. Date: Mar. 12, 2009

(54) SPUTTERING TARGETS COMPRISING A NOVEL MANUFACTURING DESIGN, METHODS OF PRODUCTION AND USES THEREOF

(76) Inventors: Janine K. Kardokus, Veradale, WA (US); Susan D. Strothers, Spokane, WA (US); Brett Clark, Spokane, WA (US); Ira G. Nolander, Spokane, WA (US); Florence A. Baldwin, Mead, WA (US); Jianxing Li, Spokane, WA (US)

Correspondence Address: BUCHALTER NEMER, 18400 VON KARMAN AVE., SUITE 800, IRVINE, CA, 92612, US

(21) Appl. No.: 11/854,064

(22) Filed: Sep. 12, 2007

(51) Int. Cl. C23C 14/00; B22D 21/00; B22D 27/00; G01N 23/00; C22C 21/12; C22C 9/01

(52) U.S. Cl. 204/298.13; 164/47; 164/66.1; 204/298.12; 250/307; 420/489; 420/529

(57) ABSTRACT

A sputtering target is described herein, which includes: a) a surface material, and b) a core material coupled to the surface material, wherein at least one of the surface material or the core material has less than 100 ppm defect volume. Methods for producing sputtering targets are described that include: a) providing at least one sputtering target material, b) melting the at least one sputtering target material to provide a molten material, c) degassing the molten material, d) pouring the molten material into a target mold. In some embodiments, pouring the molten material into a target mold comprises under-pouring or under-skimming the molten material from the crucible into the target mold. Sputtering targets and related apparatus formed by and utilizing these methods are also described herein. In addition, uses of these sputtering targets are described herein.

### FIELD OF THE SUBJECT MATTER

The field of the subject matter is sputtering targets comprising reduced numbers of defects. A novel manufacturing method is also provided, along with uses thereof.

### BACKGROUND

Electronic and semiconductor components are used in ever increasing numbers of consumer and commercial electronic products, communications products and data-exchange products. As the demand for consumer and commercial electronics increases, there is also a demand for those same products to become smaller and more portable for the consumers and businesses.

As a result of the size decrease in these products, the components that comprise the products must also become smaller and/or thinner. Examples of some of those components that need to be reduced in size or scaled down are microelectronic chip interconnections, semiconductor chip components, resistors, capacitors, printed circuit or wiring boards, wiring, keyboards, touch pads, and chip packaging.

When electronic and semiconductor components are reduced in size or scaled down, any defects that are present in the larger components are going to be exaggerated in the scaled down components. Thus, the defects that are present or could be present in the larger component should be identified and corrected, if possible, before the component is scaled down for the smaller electronic products,

In order to identify and correct defects in electronic, semiconductor and communications components, the components, the materials used and the manufacturing processes for making those components should be broken down and analyzed. Electronic, semiconductor and communication/data-exchange components are composed, in some cases, of layers of materials, such as metals, metal alloys, ceramics, inorganic materials, polymers, or organometallic materials. The layers of materials are often thin (on the order of less than a few tens of angstroms in thickness). In order to improve on the quality of the layers of materials, the process of forming the layer—such as physical vapor deposition of a metal or other compound—should be evaluated and, if possible, improved,

In a typical physical vapor deposition (PVD) process, a sample or target is bombarded with an energy source such as a plasma, laser or ion beam, until atoms are released into the surrounding atmosphere. The atoms that are released from the sputtering target travel towards the surface of a substrate (typically a silicon wafer) and coat the surface forming a thin film or layer of a material. Atoms are released from the sputtering target 10 and travel on an ion/atom path 30 towards the wafer or substrate 20, where they are deposited in a layer.

Larger sputtering targets are being manufactured in order to address larger wafers, larger applications and also in an effort to improve the consistency of the layer produced on the substrate. As the size of sputtering target increases, the demands on the mechanical integrity of the assembly increases. This presents challenges in the manufacturing of the assemblies and in the choice of materials used for the backing plate member.

In addition, when sputtering targets are produced—both conventional size and larger size targets, they can comprise defects, such as voids and inclusions. For example, sputtering copper and copper alloys targets can show arcing and on-wafer particle defects. Some of the sources of these issues can be traced back to the quality of the copper sputtering targets, and in particular to the level of voids and inclusions in the as-cast material used to fabricate the targets.

To this end, it would be desirable to produce a sputtering target and target/wafer assembly that a) can be manufactured efficiently with the minimum number of processing steps to produce the final product; b) can eliminate potential arc sources from the target and in the assembly, c) is produced by a method that reduces the number and size of inclusions and voids, d) can be produced utilizing standard molten techniques, e) comprises materials that may be degassed, and f) can comprise any material suitable for a sputtering target assembly.

### SUMMARY OF THE INVENTION

Sputtering targets are described herein, which include: a) a surface material, and b) a core material coupled to the surface material, wherein at least one of the surface material or the core material has less than 100 ppm defect volume. Sputtering targets are also described herein, which include: a) at least one surface material, and b) at least one core material coupled to the at least one surface material, wherein at least one of the surface material and the core material comprises less than about 75000 defects.

Methods for producing sputtering targets are described that include: a) providing at least one sputtering target material, b) melting the at least one sputtering target material to provide a molten material, c) degassing the molten material, d) pouring the molten material into a target mold. In some embodiments, pouring the molten material into a target mold comprises under-pouring or under-skimming the molten material from the crucible into the target mold.

Methods for producing sputtering targets are also disclosed that include: a) providing at least one alloy sputtering target material, b) providing another sputtering target material comprising at least one component from the alloy material, c) melting the sputtering target materials to provide a molten material, and d) pouring the molten material into the target mold.

Methods are also disclosed for analyzing inclusions, defects or a combination thereof in a material, that include: a) providing a liquid, b) introducing the liquid into a liquid particle counter, c) compressing the liquid, d) introducing the liquid into a laser counting cell, e) applying photons to the liquid, and f) measuring light scattering data from the liquid.

Sputtering targets and related apparatus formed by and utilizing these methods are also described herein. In addition, uses of these sputtering targets are described herein.

### BRIEF DESCRIPTION OF THE FIGURES

FIGS. 1A and 1B show a CScan analysis on low weight percent aluminum copper alloy and pure copper targets where Figures of Merit or “FOM” are shown.

FIGS. 2A and 2B show a typical degassing arrangement.

FIG. 3 shows liquid particle data for a low weight percent aluminum copper alloy.

FIG. 4 shows particle distribution in Al-0.5% Cu alloy.

FIG. 5 shows particle distribution in a pure copper target material.

FIG. 6 illustrates that conventional co-loading or Cu and Al metals for melting and casting generates high particle levels in the CuAl alloy billets because of a thermite reaction during Al melt.

FIG. 7 shows data related to the lack of thermite reaction in the modified target materials.

### DESCRIPTION OF THE SUBJECT MATTER

A sputtering target and target/wafer assembly has been produced that a) can be manufactured efficiently with the minimum number of processing steps to produce the final product; b) can eliminate potential arc sources from the target and in the assembly, c) is produced by a method that reduces the number and size of inclusions and voids, d) can be produced utilizing standard molten techniques, e) comprises materials that may be degassed, and f) can comprise any material suitable for a sputtering target assembly.

Specifically, contemplated sputtering targets comprise: a) at least one surface material, and b) at least one core material coupled to the at least one surface material, wherein at least one of the surface material and the core material comprises less than about 100 ppm defect volume. Other monolithic sputtering targets are described herein that comprise a target material, wherein the target material comprises less than about 50 ppm defect volume. In some embodiments, at least one of the surface material or the core material has less than 10 ppm defect volume. In other embodiments, at least one of the surface material or the core material has less than 5 ppm defect volume. In some embodiments, at least one of the surface material or the core material has less than 1 ppm defect volume. In yet other embodiments, at least one of the surface material or the core material has less than about 0.5 ppm defect volume,

As used herein, the phrase “defect volume” refers to the volume of defects in a surface material, target material or combination thereof. As used herein “defects”, means voids, inclusions, particles, detrimental/undesirable reaction products or a combination thereof. These inclusions and particles are those materials that are not part of the metal constituents in the surface or core materials. Defect volume may be determined by any suitable method or apparatus that can measure the volume of pores or inclusions present in a contemplated material as compared to a conventional material. For non-pore inclusions, their defect volume may be measured by taking a sample of the material and running appropriate chemical tests to determine the composition of the sample.

Defects can also be measured by the number of defects present in the sputtering target. These methods are useful in embodiments where defect volume is not readily available as a technique for measurement or analysis. Defect volume would still be the overriding principle in this analysis, but the analytical tools provide for measurement of the number of defects. Therefore, the types of defects remain the same as defined; however, the number of defects contemplated is less than 75000. In some embodiments, the number of defects is less than about 50000 defects. In other embodiments, the number of defects is less than about 20000 defects. In yet other embodiments, the number of defects is less than about 10000 defects. And in other embodiments, the number of defects is less than 1000 defects

Any suitable analytical method may be utilized to determine defect volume, number of defects, size of defects and type of defects. Some contemplated analytical methods of determining the number of defects includes those found in U.S. Pat. Nos.: 6,439,054 and 6,803,235 and PCT Publication WO 2007-081610, all of which are commonly-owned and incorporated herein in their entirety.

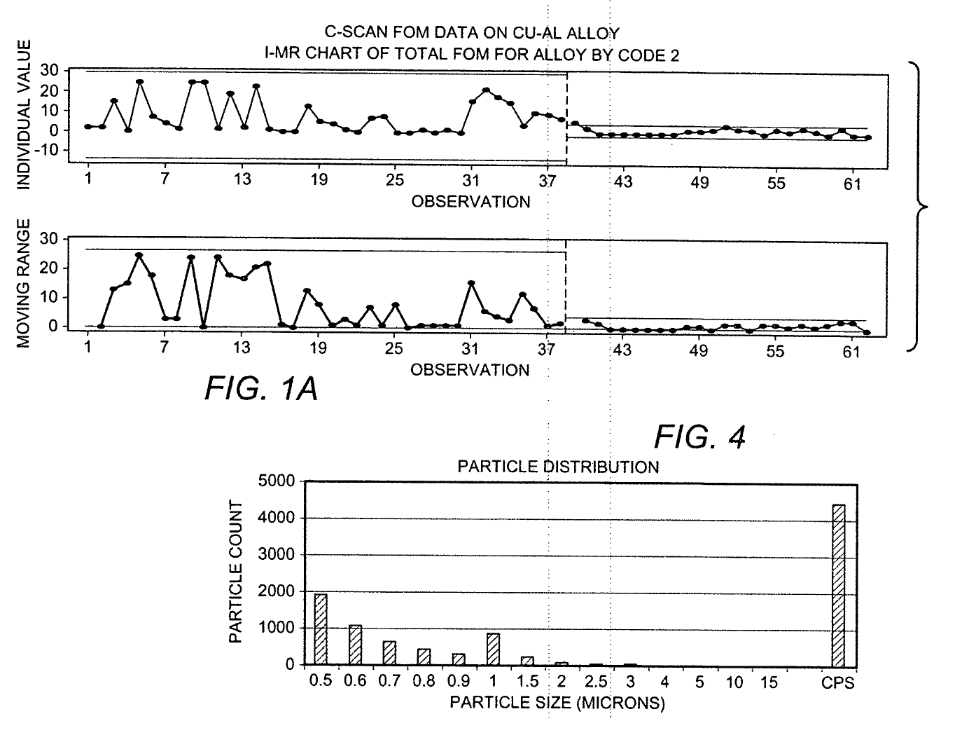

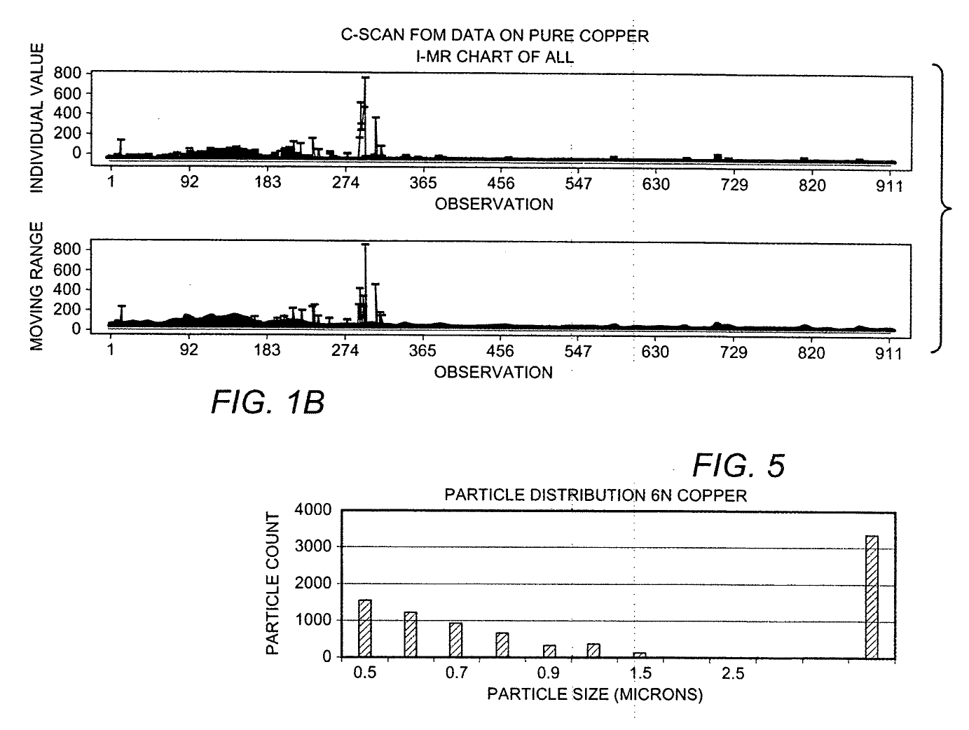

As indicated, sputtering targets contemplated herein are those comprising at least one surface material, and at least one core material coupled to the at least one surface material, wherein at least one of the surface material and the core material comprises less than about 100 ppm defect volume. As mentioned, defect volume can refer to the volume of pores, inclusions, particles or combinations thereof in a material. As used herein, the terms “avoid” and “pore” mean a free volume in which a mass is replaced with a gas or where a vacuum is generated. It is intended that the terms pore and void can be used interchangeably herein. Voids found in additionally have any shape, including tubular, lamellar, discoidal, or other shapes. It is also contemplated that the voids may have any appropriate diameter. It is further contemplated that at least some voids may connect with adjacent voids to create a structure with a significant amount of connected or “open” porosity. Contemplated voids will have a mean diameter of less than 2000 microns. In some embodiments, voids will have a mean diameter of less than 1000 microns. In other embodiments, voids will have a mean diameter of less than 500 microns. In yet other embodiments, voids will have a mean diameter of less than 100 microns. In other embodiments, voids will have a mean diameter of less than 10 microns. In order to detect some and/or all of the voids, a CScan process is utilized. FIGS. 1A and 1B shows a CScan analysis on low weight percent aluminum copper alloy (A) and pure copper targets (B) where Figures of Merit or “FOM” are shown for both a baseline or standard process contrasted with the process contemplated herein. The results of the standard process of manufacture is shown on the left of the graphs, and the results of the modified process described herein is shown on the right of the graphs.

In other embodiments, inclusions are formed or found in the target material. As used herein, the term “inclusions” means those particles, substances or compositions of mater that are found in the target material, which are not intended as part of the desirable target material. Inclusions contemplated herein may also comprise any suitable shape and generally are less than about 500 microns in diameter or average diameter. In some embodiments, contemplated inclusions are less than about 100 microns in diameter or average diameter. In other embodiments, contemplated inclusions are less than about 50 microns in diameter or average diameter. In some embodiments, contemplated inclusions are less than about 10 microns in diameter or average diameter. In yet other embodiments, contemplated inclusions are less than about 1 micron in diameter or average diameter. In other embodiments, inclusions contemplated herein may have a diameter or average diameter less than about 500 nanometers. In yet other embodiments, inclusions contemplated herein may have a diameter or average diameter less than about 100 nanometers.

In some embodiments, these inclusions include undesirable or damaging reaction products. For example, in the formation of an aluminum-copper alloy target, the utilization of a pure aluminum charge causes a thermite reaction resulting in a high particle count on the surface of the melt. This type of reaction will be shown in further detail in the Examples Section.

Sputtering targets and sputtering target assemblies contemplated and produced herein comprise any suitable shape and size depending on the application and instrumentation used in the PVD process. Sputtering targets contemplated and produced herein comprise a surface material and a core material (which includes the backing plate). The surface material and core material may generally comprise the same elemental makeup or chemical composition/component, or the elemental makeup and chemical composition of the surface material may be altered or modified to be different than that of the core material. However, in embodiments where it may be important to detect when the target's useful life has ended or where it is important to deposit a mixed layer of materials, the surface material and the core material may be tailored to comprise a different elemental makeup or chemical composition In some embodiments, the surface material and the core material are the same in order to produce a monolithic target. The surface material is that portion of the target that is intended to produce atoms and/or molecules that are deposited via deposition to form the surface coating/thin film.

Sputtering targets contemplated herein may generally comprise any material that can be a) reliably formed into a sputtering target; b) sputtered from the target when bombarded by an energy source; and c) suitable for forming a final or precursor layer on a wafer or surface, d) material that can be cast and degassed, and e) materials that have a melting point less than that of iron. Materials that are contemplated to make suitable sputtering targets are metals, metal alloys, hard mask materials and any other suitable sputtering material. Some materials disclosed herein do not have a melting point or effective melting point less than iron on their own, but when alloyed or combined with other materials, those new materials can have a melting point or effective melting point less than that of iron. Therefore, this benchmark of the melting point of iron is the key consideration when determining whether a particular material is appropriate.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Some contemplated metals include silicon, cobalt, copper, nickel, iron, zinc, aluminum and aluminum-based materials, tin, gold, silver, or a combination thereof. Other contemplated metals include copper, aluminum, cobalt, magnesium, manganese, iron or a combination thereof. Examples of contemplated materials, include aluminum and copper for superfine grained aluminum and copper sputtering targets; aluminum, copper or cobalt for use in 200 mm and 300 mm sputtering targets, along with other mm-sized targets; and aluminum for use in aluminum sputtering targets that deposit a thin, high conformal “seed” layer or “blanket” layer of aluminum surface layers. It should be understood that the phrase “and combinations thereof” is herein used to mean that there may be metal impurities in some of the sputtering targets, such as a copper sputtering target with chromium and aluminum impurities, or there may be an intentional combination of metals and other materials that make up the sputtering target, such as those targets comprising alloys, borides, fluorides, nitrides, silicides and others.

The term “metal” also includes alloys. Alloys contemplated herein comprise gold, antimony, arsenic, aluminum, boron, copper, germanium, nickel, indium, phosphorus, silicon, cobalt, vanadium, iron, hafnium, titanium, iridium, zirconium, silver, tin, zinc, rhenium, rhodium and combinations thereof. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, silver copper, silver gallium, silver gold, aluminum copper, aluminum silicon, aluminum silicon copper, aluminum titanium, chromium copper, and/or combinations thereof. In some embodiments, contemplated materials include those materials disclosed in U.S. Pat. No. 6,331,233, which is commonly-owned by Honeywell International Inc., and which is incorporated herein in its entirety by reference.

Metals and alloys contemplated herein may also comprise other metals in smaller amounts. These metals may be naturally-occurring in certain target formations or may be added during the target production It is contemplated that these metals either provide no change to the overall target properties or are designed to improve the target properties. However, it should be emphasized again that the benchmark for any sputtering target metal or alloy its effective melting point is below that of iron. In one example, copper can be used as a suitable target material. When using copper as a target material, there are several metal additives that can be included with the copper material without raising the melting point above that of iron, including silver, gold, aluminum, iron, indium, magnesium, manganese, nickel, tin and zinc. Additional materials that are considered viable, but are considered as less conventional materials, include Am, B, Ba, Be, Bi, Ca, Ce, Co, Dy, Eu, Ga, Gd, Ge, Hf, Ho, La, Li, Lu, Nd, P, Pb, Pm, Pr, Pu, Sb, Sc, Sm, Sr, Tb, Th, T, Tm, Y and Yb. Silicon, iridium and titanium may also have a limited viability at lower atomic concentrations with a copper-based sputtering target. Materials that are not considered viable because of either temperature or volatility include C, Cr, Mo, Na, Nb, Os, Pd, Pt, Re, Rh, Ta, Tc, U, V, W, As, Cd, Cl, F, H, Hg, S, Se, Te.

Methods for producing sputtering targets are described that include: a) providing at least one sputtering target material, b) melting the at least one sputtering target material to provide a molten material, and c) pouring the molten material into the target mold. In some embodiments, contemplated methods include a) providing at least one sputtering target material, b) melting the at least one sputtering target material to provide a molten material, c) degassing the molten material, d) pouring the molten material into a target mold. In some embodiments, pouring the molten material into a target mold comprises under-pouring or under-skimming the molten material from the crucible or container into the target mold.

In other embodiments, methods for producing sputtering targets are described that include: a) providing at least one alloy sputtering target material, b) providing another sputtering target material comprising at least one component from the alloy material, c) melting the sputtering target materials to provide a molten material, and d) pouring the molten material into the target mold. In these embodiments, along with other embodiments disclosed herein, other desirable components may be added to the target material before target formation, as mentioned earlier. In some embodiments, these desirable components include Al, Cs, Mg, Sr, Sc, Y, Ti, Zr, Hf, Mn, the La series or a combination thereof.

In the methods contemplated herein, especially those that comprise copper alloys, aluminum alloys or combinations thereof, the copper alloy or aluminum alloy comprises CuxAl or AlxCu, wherein x is less than about 30 weight percent. In some embodiments, the copper alloy or aluminum alloy comprises CuxAl or AlxCu, wherein x is from about 0.5 weight percent to about 30 weight percent.

The at least one sputtering target material may be any of those materials previously described herein. The at least one sputtering target material may be provided by any suitable method, including a) buying the at least one from a supplier; b) preparing or producing the at least one sputtering target material in house using materials provided by another source and/or c) preparing or producing the at least one sputtering target material in house using materials also produced or provided in house or at the location. In some embodiments, methods are described that further provide for optimizing the grain structure of the target material. In other embodiments, the methods will further comprise utilizing at least one machining step to form the target.

The at least one sputtering target material may be melted to provide a molten material. As contemplated herein, the at least one sputtering target material may be melted in any suitable fashion and in any suitable container or crucible. A suitable container or crucible is one that is constructed out of a material or materials that are compatible with the at least one sputtering target material being melted. By using the term “compatible” it is meant that the container or crucible material will not interfere or contaminate the at least one sputtering target material being melted in the container or crucible. In some embodiments, vacuum induction melting (VIM) is used to melt metals and alloys.

In addition, the container or crucible should be able to withstand the temperatures necessary to melt the at least one sputtering target material, while at the same time not interfering or contaminating the at least one sputtering target material. This consideration can be very important when attempting to minimize the number and size of inclusions in the molten material. Crucibles that are more common in the aluminum bronze industry, such as silicon carbide crucibles, might be feasible for applications and methods contemplated herein. In some embodiments, a high density, high purity graphite crucible can be coated with boron nitride to control contamination of the molten material.

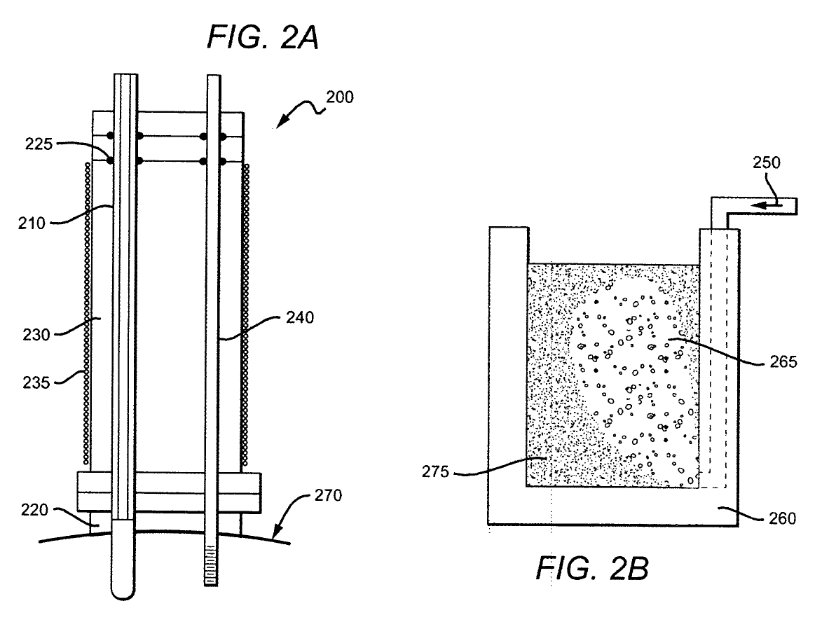

Once the molten material is formed, it must be degassed according to the methods provided herein in order to ensure that the numbers of voids, inclusions or combination thereof are minimized. Degassing is achieved by bubbling an inert gas, such as argon or nitrogen, through the molten material prior to pouring. Degassing can be done by running the gas through the side walls of the crucible or container and/or up through the bottom of the melt. Degassing may also be accomplished by using a degassing apparatus, method or combination thereof, such as a degassing wand that is inserted into the top of the molten material, a side-wall degassing method or apparatus, or a combination thereof. A typical degassing arrangement is shown in FIGS. 2A and 2B. In FIG. 2A, a contemplated degassing arrangement 200, which is designed to fit an existing port on a VIM apparatus 270, is shown comprising a ¾′ degassing rod assembly 210 with a graphite tip 220, which is about 9′ long. A ½′ alloy adder rod 240 having a ½-13 thread to accept various alloy adders (hook, claw, shovel) is located next to the degassing rod assembly. Vacuum tight seals 225 and a water cooling tower 230 surround in part or in whole the rods. Cooling coils 235 surround the entire degassing arrangement 200. The degassing arrangement stands a total of about 96″ high, wherein the towers stand about 48″ and the rods stand an additional 48″, The degassing process is shown in FIG. 2B, where the degassing arrangement (not shown) is used to force gas 250 into the bottom of the crucible 260 and force any defects 265 out of the molten material 275.

One example is bubbling the molten material—in the form of copper melts—with argon or dry nitrogen through graphite lances, which is a technique commonly used for degassing aircraft quality aluminum bronzes. The objective here is to remove hydrogen from the melt. For the size of melt that is contemplated, 15-20 minutes would be sufficient, and in some embodiments, 4-5 minutes is sufficient. Nitrogen should not have appreciable solubility in the copper. In conventional sputtering target production without degassing, small round pores with shiny surfaces are observed in sections of the as-cast material, and this observation confirms the presence of hydrogen bubbles. It should be understood that a vacuum will not be sufficient to get these voids out of the molten material.

In the next step, the molten material is poured into a suitable mold. One might consider utilizing filtration to remove inclusions, but filtration is not commonly used in some molten materials—like copper—like it is with aluminum melts. It seems that in place of filtration, pouring the metal from under the top skin of the melt (under-pouring, under-skimming or under-pulling) is desirable. Another method of pouring the molten material is the Delavand method, which is somewhat analogous to pouring beer down the side of a glass to minimize foaming. In the prior method, which comprises under-pouring, under-skimming or under-pulling, a tundish with a large central hole (˜½ diameter) with a tapered stopper can be implemented that can be lifted up and down to control the metal flow. The stopper should be down when the tundish is filled and before raising the stopper and starting to pour into the mold. The tundish can be refilled with molten copper as the molten material, and this design should allow the melt to be under-poured. In some embodiments, it is desirable to have a tundish design that can rise as the casting process proceeds, with the feed tube from the tundish extending about an inch below the melt surface. (Note that this arrangement would significantly reduce turbulence during pouring.) Typical practice in the aluminum bronze industry is to under-pour from a ladle.

The methods and apparatus described herein are especially useful in producing unconventional, uniquely-sized targets, such as the 300 mm ULVAC Entron EX PVD target and new targets being produced to utilize in the production of large LCD and plasma displays.

Liquid particle analysis—as contemplated—is a method whereby the size and number of particles in a plating solution, dissolved metal or other solution can determined. This analysis allows monitoring of the solution or material for potential contaminates or detects, as contemplated herein. The solution or material is prepared for liquid particle analysis by dissolving the sample, which includes providing a solid sample, dissolving the sample by utilizing acid. In this method, the material, such as copper, aluminum or a combination thereof, is dissolved and the inclusions, defects or combinations thereof stay in solution. The method could also be applied to the analysis of other solutions where particulate contaminates pose a risk to quality or reliability. As contemplated, methods contemplated herein comprise: a) providing a liquid material, b) introducing the liquid material into a liquid particle counter, c) compressing the liquid material, d) introducing the liquid material into a laser counting cell, e) applying photons to the liquid material, and f) measuring light scattering data from the liquid material. Specifically, the method involves taking the solution or material directly from the source and introducing it into a liquid particle counter.

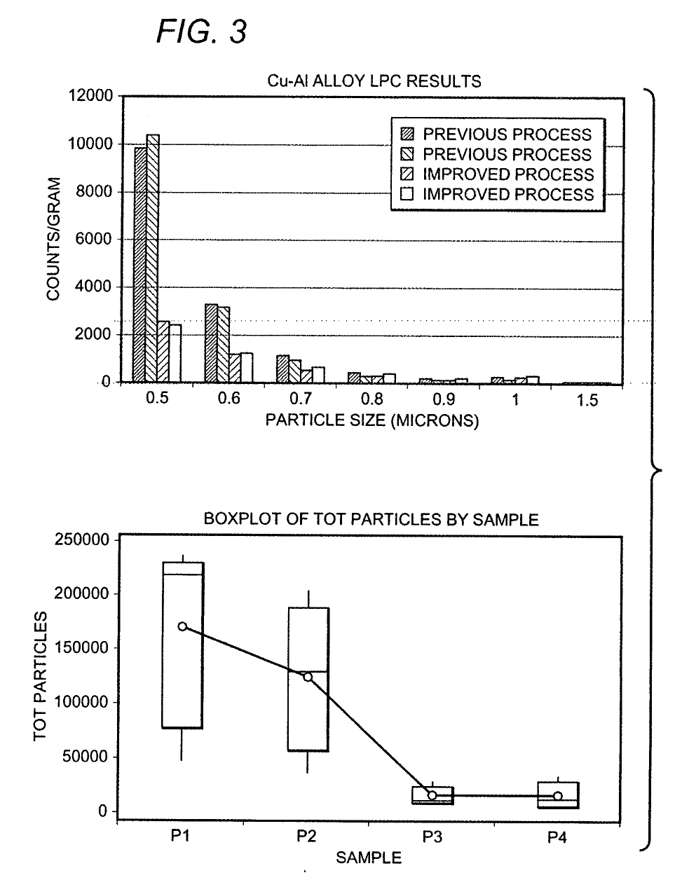

The counter includes a pressurized sampler that can accommodate corrosive liquids in series with a laser counting cell. The liquid is compressed to remove any air bubbles, and the solution is then pumped through the laser counting cell. The light scattering is measured by an array of photodetectors, and the scattering pattern is characteristic of the particle size. The counter can detect particles in a range from 100 to 0.2 micrometers. One method of utilizing liquid particle analysis can be found in PCT Publication WO 2007-081610, which is commonly-owned and incorporated herein in its entirety by reference. FIGS. 3-5 show a liquid particle analysis of low weight percent aluminum copper alloy and pure copper target materials. FIG. 3 shows liquid particle data for a low weight percent aluminum copper alloy. FIG. 4 shows particle distribution in Al-0.5% Cu alloy. FIG. 5 shows particle distribution in a pure copper target material.

### EXAMPLES

### Example 1

### Copper/Aluminum Alloy Sputtering Target [Master Alloy Production by Continuous Casting]

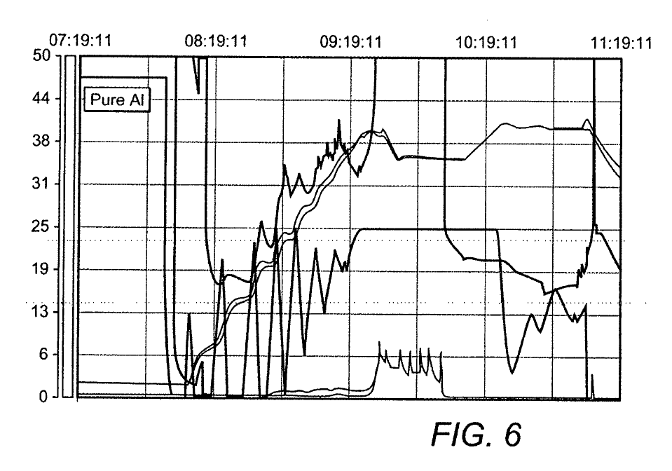

A CuAl alloy sputtering target is used for Cu seed layer deposition in dual damascene process or Al conductor in subtractive process. The alloy requires homogeneous Cu or Al distribution in the deposited layer, along with a low particle level. Conventional co-load Cu and Al metal for melt and cast generates high particle level in the CuAl alloy billets because of thermite reaction during Al melt, which is illustrated in FIG. 6—a furnace crucible temperature historical trend graph. One example is a copper alloy with a low weight percent of aluminum, such as 0-5% weight percent aluminum. This type of target may be used for copper seed layer deposition in dual damascene process for 65 nm technology node and beyond.

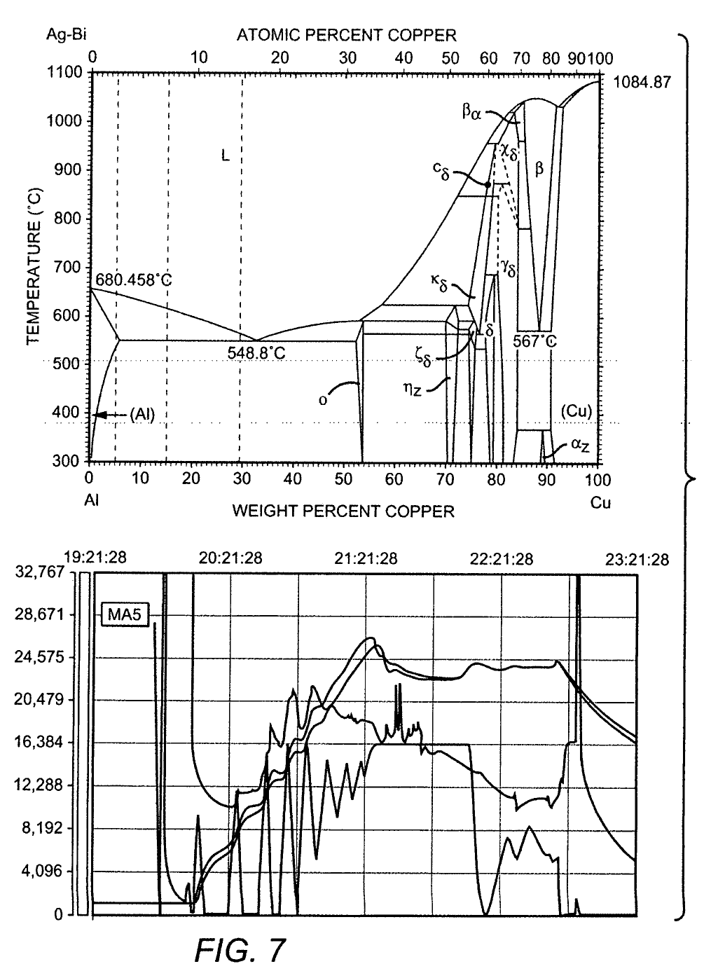

Contemplated processes use a continuous cast AlCu master alloy to replace pure Al, in order to suppress the thermite reaction during the melt. The Al from the master alloy is in the form of Al(Cu) solid solution and wetted by Cu, which greatly reduces the thermite reaction during the melt process. The result is a simple one-step VIM process with homogenous Al distribution and low particle CuAl alloy billets. Data related to the lack of thermite reaction in the modified target materials is shown in FIG. 7—a furnace crucible temperature historical trend graph.

### Master Alloy Fabrication by VIM [Comparative] (Using Al5Cu as an Example)

Co-load Cu and Al metal in a ratio of 95 wt % Al and 5 wt % Cu in a graphite or a ceramic lined crucible in a VIM, melt the mix to form a homogenous Al5Cu alloy, cool the alloy in the crucible slowly from bottom up to exclude impurity and particle to top of the billet. Crop the top of the billet and use the remaining portion as the master alloy for a low aluminum weight percent copper alloy feed charge. Co-load Cu and Al metals in a ratio of 95% Al and 5 wt % Cu in a graphite crucible in a induction melter, melt the mix to form a homogenous Al5Cu alloy, cast the alloy continuously into a Al5Cu alloy billet for the low aluminum weight percent copper alloy feed charge. The master alloy composition can be 0.5-30 wt % Cu with balance Al.

### CuAl Alloy Fabrication (Using a Low Aluminum Weight Percent Copper Alloy as an Example)

Co-load Cu and the CuAl master alloy with appropriate ratio for the low aluminum weight percent copper alloy composition, melt the mix using conventional Cu melt recipe and cast the alloy into graphite molds to get homogeneous alloy billets with low particles. The target alloy composition can be 0.5-5 wt % Al with balance Cu, or 0.5-5 wt % Cu with balance Al.

Thus, specific embodiments and applications of methods of manufacturing sputtering targets and related apparatus have been disclosed. It should be apparent, however, to those skilled in the art that many more modifications besides those already described are possible without departing from the inventive concepts herein. The inventive subject matter, therefore, is not to be restricted except in the spirit of the disclosure and claims herein. Moreover, in interpreting the disclosure and claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A sputtering target, comprising:
at least one surface material, and
at least one core material coupled to the at least one surface material,
wherein at least one of the surface material and the core material comprises less than about 100 ppm defect volume.

2. The sputtering target of claim 1, wherein the at least one surface material and the at least one core material comprise the same material, materials to or combination thereof.

3. The sputtering target of claim 1, wherein the at least one surface material comprises at least one transition metal.

4. The sputtering target of claim 3, wherein the at least one transition metal comprises copper, aluminum or a combination thereof.

5. The sputtering target of claim 1, wherein the at least one surface material comprises copper, aluminum, a copper alloy, an aluminum alloy, or a combination thereof.

6. The sputtering target of claim 5, wherein the at least one surface material material comprises CuxAl or AlxCu, wherein x is less than about 30 weight percent.

7. The sputtering target of claim 5, wherein the at least one surface material material comprises CuxAl or AlxCu, wherein x is from about 0.5 weight percent to about 30 weight percent.

8. The sputtering target of claim 1, wherein the at least one of the surface material and the core material comprises less than about 10 ppm defect volume.

9. The sputtering target of claim 8, wherein the at least one of the surface material and the core material comprises less than about 1 ppm defect volume.

10. The sputtering target of claim 2, wherein the sputtering target is monolithic.

11. A method for producing a sputtering target, comprising:
providing at least one sputtering target material,
melting the at least one sputtering target material to provide a molten material,
degassing the molten material, and
pouring the molten material into a target mold.

12. The method of claim 11, wherein pouring the molten material comprises under-pouring the molten material into a target mold.

13. The method of claim 11, wherein pouring the molten material comprises under-skimming the molten material into a target mold.

14. The method of claim 11, wherein the at least one sputtering target material has an effective melting point less than that of iron.

15. The method of claim 11, wherein the at least one sputtering target material comprises at least one transition metal.

16. The method of claim 15, wherein the at least one transition metal comprises copper, aluminum or a combination thereof.

17. The method of claim 15, wherein the at least one sputtering target material comprises copper, aluminum, a copper alloy, an aluminum alloy, or a combination thereof.

18. The method of claim 17, wherein the copper alloy or aluminum alloy comprises CuxAl or AlxCu, wherein x is less than about 30 weight percent.

19. The method of claim 18, wherein the copper alloy or aluminum alloy comprises CuxAl or AlxCu, wherein x is from about 0.5 weight percent to about 30 weight percent.

20. The method of claim 1, wherein the sputtering target comprises less than about 100 ppm defect volume.

21. The method of claim 20, wherein the sputtering target comprises less than about 10 ppm detect volume.

22. The method of claim 21, wherein the sputtering target comprises less than about 1 ppm defect volume.

23. The method of claim 11, wherein degassing the molten material comprises utilizing an inert gas.

24. The method of claim 23, wherein the inert gas comprises argon or nitrogen.

25. The method of claim 11, wherein degassing the molten material comprises utilizing a degassing apparatus, degassing method or combination thereof.

26. The method of claim 25, wherein the degassing apparatus comprises a degassing wand.

27. The method of claim 25, wherein the degassing method comprises a side-wall degassing method.

28. A sputtering target produced using the method of claim 11.

29. A method of analyzing inclusions, defects or a combination thereof in a material, comprising:
providing a liquid,
introducing the liquid into a liquid particle counter,
compressing the liquid,
introducing the liquid into a laser counting cell,
applying photons to the liquid, and
measuring light scattering data from the liquid.

30. The method of claim 29, wherein the liquid comprises copper, aluminum or combinations thereof.

31. The method of claim 29, wherein the liquid comprises at least one inclusion, defect or combination thereof.

32. A method for producing a sputtering target, comprising:
providing at least one alloy sputtering target material,
providing another sputtering target material comprising at least one component from the alloy material,
melting the sputtering target materials to provide a molten material, and
pouring the molten material into the target mold.

33. The method of claim 32, wherein pouring the molten material comprises under-pouring the molten material into a target mold.

34. The method of claim 32, wherein pouring the molten material comprises under-skimming the molten material into a target mold.

35. The method of claim 32, wherein the at least one sputtering target material, the at least one alloy sputtering target material or a combination thereof has an effective melting point less than that of iron.

36. The method of claim 32, wherein the alloy sputtering target material comprises copper, aluminum or a combination thereof.

37. The method of claim 36, wherein the alloy sputtering target material comprises CuxAl or AlxCu, wherein x is less than about 30 weight percent.

38. The method of claim 37, wherein the alloy sputtering target material comprises CuxAl or AlxCu, wherein x is from about 0.5 weight percent to about 30 weight percent.

39. The method of claim 32, wherein the molten material comprises at least one element having a high oxygen affinity.

40. The method of claim 39, wherein the at least one element comprises Al, Cs, Mg, Sr, Sc, Y, Ti, Zr, Hf, Mn, the La series or a combination thereof.

41. A sputtering target produced from the method of claim 32.

42. The sputtering target of claim 1, comprising:
at least one surface material, and
at least one core material coupled to the at least one surface material,
wherein at least one of the surface material and the core material comprises less than about 75000 defects.

43. The sputtering target of claim 42, wherein the at least one of the surface material and the core material comprises less than about 50000 defects.

44. The sputtering target of claim 43, wherein the at least one of the surface material and the core material comprises less than about 25000 defects.

45. The sputtering target of claim 44, wherein the at least one of the surface material and the core material comprises less than about 10000 defects.

46. A sputtering target, comprising:
at least one surface material, and
at least one core material coupled to the at least one surface material,
wherein at least one of the surface material and the core material comprises less than about 75000 defects.

47. The sputtering target of claim 46, wherein the at least one of the surface material and the core material comprises less than about 50000 defects.

48. The sputtering target of claim 47, wherein the at least one of the surface material and the core material comprises less than about 25000 defects.

49. The sputtering target of claim 48, wherein the at least one of the surface material and the core material comprises less than about 10000 defects.
